(19) United States
(12) Patent Application Publication
(10) Pub. No.: US 2023/0065064 A1
(43) Pub. Date: Mar. 2, 2023

(54) COATED TURBOMACHINE PART HAVING A NICKEL-BASED SUBSTRATE COMPRISING HAFNIUM

(71) Applicants: SAFRAN AIRCRAFT ENGINES, PARIS (FR); SAFRAN, PARIS (FR); CENTRE NATIONAL DE LA RECHERCHE SCIENTIFIQUE, PARIS (FR); UNIVERSITE DE LA ROCHELLE, LA ROCHELLE (FR)

(72) Inventors: Joel DELAUTRE, MOISSY-CRAMAYEL (FR); Sarah HAMADI, MOISSY-CRAMAYEL (FR); Annie PASQUET, MOISSY-CRAMAYEL (FR); Virginie JAQUET, MOISSY-CRAMAYEL (FR); Fernando PEDRAZA DIAZ, LA ROCHELLE (FR); Christophe Philippe AUDIC, MOISSY-CRAMAYEL (FR)

(21) Appl. No.: 17/797,947

(22) PCT Filed: Feb. 1, 2021
(86) PCT No.: PCT/FR2021/050180

§ 371 Date: Aug. 5, 2022

(30) Foreign Application Priority Data
Feb. 6, 2020 (FR) FR2001165

(51) Int. Cl. F01D 5/28; C22C 19/05; C30B 29/52

(52) U.S. Cl. CPC F01D 5/28; C22C 19/057; C30B 29/52; F05D 2220/323; F05D 2240/30; F05D 2300/175

(57) ABSTRACT

A turbomachine part includes (i) a nickel-based superalloy substrate including, in mass content, 5.0% to 8.0% cobalt, 6.5% to 10% chromium, 0.5% to 2.5% molybdenum, 5.0% to 9.0% tungsten, 6.0% to 9.0% tantalum, 4.5% to 5.8% aluminum, hafnium in a mass content greater than or equal to 2000 ppm, and optionally including niobium in a mass content less than or equal to 1.5%, and optionally at least one of carbon, zirconium and boron each in a mass content less than or equal to 100 ppm, the remainder being composed of nickel and unavoidable impurities; and (ii) a β-structured nickel aluminide coating covering the substrate.

### TECHNICAL FIELD

The present invention relates to the field of nickel-based superalloys and more precisely to superalloys used in the aeronautical field.

### PRIOR ART

It is known that nickel-based superalloys have, on the one hand, high mechanical strength even at high temperature and, on the other hand, good resistance to oxidation. Due to these two properties, they represent a material of choice for parts of turbomachines used in the aeronautical field.

Among the known nickel-based superalloys, mention may notably be made of the alloy with the trade name AM-1 corresponding to the composition described in the document U.S. Pat. No. 4,639,280,

The oxidation resistance of superalloys can be further enhanced by coatings formed on their surface. However, even with such coatings, AM-1 based alloys currently available eventually oxidize when used in a turbomachine. Thus, it remains desirable to further improve the oxidation resistance of superalloys for turbomachine part.

### DISCLOSURE OF THE INVENTION

To that end, the inventors provide a turbomachine part comprising:

(i) a nickel-based superalloy substrate comprising, in mass content, 5.0% to 8.0% cobalt, 6.5% to 10% chromium, 0.5% to 2.5% molybdenum, 5.0% to 9.0% tungsten, 6.0% to 9.0% tantalum, 4.5% to 5.8% aluminum, hafnium in a mass content greater than or equal to 2000 ppm, and optionally comprising niobium in a mass content less than or equal to 1.5%, and optionally at least one of carbon, zirconium and boron each in a mass content less than or equal to 100 ppm, the remainder being composed of nickel and unavoidable impurities; and

(ii) a β-structured nickel aluminide coating covering the substrate.

Preferably, the hafnium mass content is less than or equal to 15,000 ppm.

The invention provides a turbomachine part formed by a substrate having a composition similar to AM-1 but modified so as to have a relatively high hafnium content, of at least 2000 ppm, and coated with a β-structured nickel aluminide. The inventors have observed that this part formed from such a substrate coated with this specific coating has a particularly high oxidation resistance. Without wishing to be bound by theory, the inventors consider that the limited carbon content in the substrate contributes to improving the oxidation resistance of the part by ensuring that the hafnium is available to migrate to the surface and form a protective oxide, rather than being trapped as carbide in the material,

Preferably, the hafnium mass content in the substrate may be greater than or equal to 4000 ppm.

In a preferred embodiment, the hafnium mass content in the substrate may be greater than or equal to 6000 ppm,

The inventors have found that the higher the hafnium content, the better the oxidation resistance.

In one embodiment, the superalloy is monocrystalline. A monocrystalline superalloy allows a faster migration of the hafnium and in greater quantity towards the surface since the hafnium is not trapped by the carbon generally introduced to stabilize the grain boundaries of a polycrystalline alloy. This further improves the protection imparted by the hafnium and therefore the oxidation resistance of the part.

In one embodiment, the β-structured nickel aluminide coating may be β-structured NiAl. It will be noted that generally the β-structured nickel aluminide coating may or not be modified by one or more elements, for example platinum, zirconium or hafnium. Thus, as a β-structured nickel aluminide coating suitable for the invention, mention may in particular be made of β-structured NiAl, β-structured NiPtAl, β-structured NiAlZr and β-structured NiAlHf.

In one embodiment, the β-structured nickel aluminide coating is a β-structured NiAl coating or a β-structured NiPtAl coating.

The β-structured nickel aluminide coating can be formed by a method known per se. For instance, the formation of the β-structured nickel aluminide can in particular be carried out by physical vapor deposition, by chemical vapor deposition, by solid carburizing or via a slurry process.

In one embodiment, a turbomachine part according to the invention may further comprise a thermal barrier present on the β-structured nickel aluminide coating.

Such a thermal barrier is known per se, and makes it possible to protect the turbomachine part against the high temperatures which it encounters during its use.

In one embodiment, the thermal barrier may be present in contact with the β-structured nickel aluminide coating.

In one embodiment, the turbomachine part may be a turbomachine distributor or a turbomachine distributor sector. The distributor can be a high pressure distributor or a low pressure distributor.

In alternative embodiments, the turbomachine part may also be a moving vane or a turbine ring sector.

According to another of its aspects, the invention also relates to a turbomachine comprising a part as described above.

### BRIEF DESCRIPTION OF THE FIGURES

FIG. 1 shows schematically and partially a portion of a turbomachine distributor according to one embodiment of the invention.

FIG. 2 shows schematically and partially a sectional view of a turbomachine part according to one embodiment of the invention.

FIG. 3 is a comparative test result showing the differences in terms of oxidation resistance between parts according to the invention and parts outside the invention.

### DETAILED DESCRIPTION

The description will now be given by means of figures aimed at better understanding the invention but which should in no way be interpreted in a limiting manner.

Conventionally, a turbomachine turbine comprises stationary elements and movable elements. The movable elements can be movable wheels carrying vanes, and are generally interposed between sets of stationary vanes, also called distributor. The distributor/movable wheel pair forms a turbine stage.

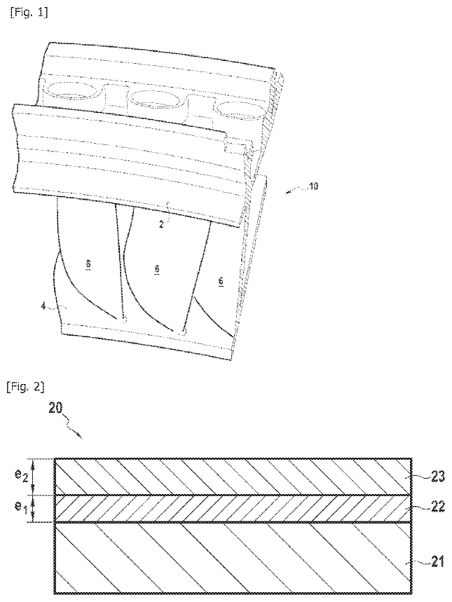

FIG. 1 represents a portion of a turbomachine distributor 10.

A turbomachine distributor 10 may include an outer platform 2 and an inner platform 4, between which extend stationary vanes 6, intended to direct the air flow in a direction favorable to the drive of the adjacent moveable wheel, not shown.

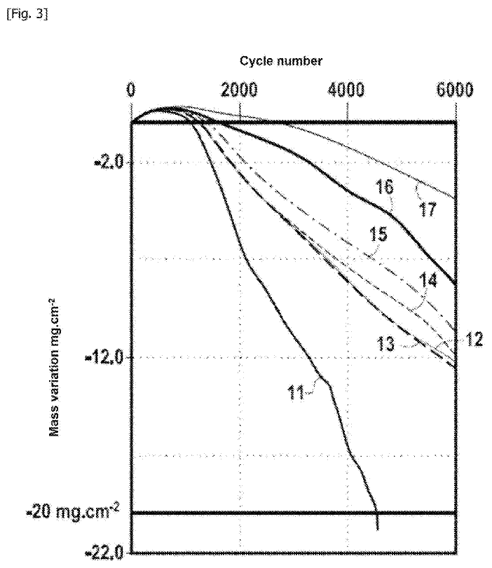

FIG. 2 shows schematically a turbomachine part 20 composed of a substrate 21 and a β-structured nickel aluminide coating 22 which covers the underlying substrate 21.

In addition, in the embodiment shown, the turbomachine part 20 further comprises a thermal barrier 23 in contact with the β-structured nickel aluminide coating 22. The thermal barrier 23 can define the outer surface of the part 20.

In one embodiment, the coating 22 may have a thickness e₁ between 40 μm and 90 μm.

Likewise, the thermal barrier 23 may have a thickness e₂ between 50 μm and 300 μm.

In one embodiment, the thermal barrier can be chosen from a zirconia partially stabilized with yttria or one or more other rare earth oxide(s), a zirconia doped with dysprosium, gadolinium zirconate, a perovskite.

In an alternative embodiment, the thermal barrier 23 may be absent. In this case, the β-structured nickel aluminide coating 22 can define the outer surface of the part.

### EXAMPLE

Several AM-1 samples were enriched with a hafnium mass content ranging from 340 ppm to 8000 ppm. Samples according to the invention are thus produced when the hafnium level is greater than or equal to 2000 ppm, and others are produced outside the invention.

The samples vary only in their hafnium mass contents.

The hafnium content of the samples thus prepared is measured by mass spectrometry. Samples are coated with a platinum-modified β-structured nickel aluminide NiPtAl coating. Each sample is then subjected to oxidation cycles, and the mass change of each sample is measured three times a week for the first 200 cycles, then twice a week thereafter.

An oxidation cycle corresponds to a very fast heating up to the oxidation temperature (1150° C.±5° C.), a holding at 1150° C. under atmospheric air pressure for 60 minutes and finally a forced cooling with dry air for 15 minutes to ensure that the room temperature is below 150° C.±3° C. The test is stopped after 6000 oxidation cycles or when a specific mass variation of 20 mg/cm² is observed.

FIG. 3 illustrates the results obtained for each sample. The hafnium mass contents of the samples represented in FIG. 3 are 340 ppm for curve 11, 780 ppm for curve 12, 670 ppm for curve 13, 1300 ppm for curve 14, 2100 ppm for curve 15, 4700 ppm for curve 16 and 8000 ppm for curve 17.

It can be seen in FIG. 3 that the samples with a hafnium content greater than 2000 ppm (15, 16, 17) are also those for which the mass loss is the least important. The high hafnium content therefore allows a better oxidation resistance.

The expression “between . . . and . . . ” should be understood as including the limits.

1. A turbomachine part comprising:
(i) a nickel-based superalloy substrate comprising, in mass content, 5.0% to 8.0% cobalt, 6.5% to 10% chromium, 0.5% to 2.5% molybdenum, 5.0% to 9.0% tungsten, 6.0% to 9.0% tantalum, 4.5% to 5.8% aluminum, hafnium in a mass content greater than or equal to 2000 ppm, and optionally comprising niobium in a mass content less than or equal to 1.5%, and optionally at least one of carbon, zirconium and boron each in a mass content less than or equal to 100 ppm, the remainder being composed of nickel and unavoidable impurities; and
(ii) a β-structured nickel aluminide coating covering the substrate.

2. The turbomachine part according to claim 1, wherein the hafnium mass content in the substrate is greater than or equal to 4000 ppm.

3. The turbomachine part according to claim 2, wherein the hafnium mass content in the substrate is greater than or equal to 6000 ppm.

4. The turbomachine part according to claim 1, further comprising a thermal barrier present on the β-structured nickel aluminide coating.

5. The turbomachine part according to claim 1, wherein the β-structured nickel aluminide coating is a β-structured NiAl coating or β-structured NiPtAl coating.

6. The turbomachine part according to claim 1, wherein the superalloy is monocrystalline.

7. The turbomachine part according to claim 1, wherein said part is a turbomachine distributor or a turbomachine distributor sector.

8. A turbomachine comprising a turbomachine part according to claim 1.
